(19) United States
(12) Patent Application Publication
(10) Pub. No.: US 2026/0203457 A1
(43) Pub. Date: Jul. 16, 2026

(54) Evaluation Method and System for Impacts of Groundwater Level Fluctuations on Safety of Subway Stations Based on Centrifugal Model Tests and Storage Medium

(71) Applicants: CHINA INSTITUTE OF WATER RESOURCES AND HYDROPOWER RESEARCH, BEIJING (CN); China University of Geosciences (Beijing), BEIJING (CN)

(72) Inventors: Shu YU, BEIJING (CN); Yijie WANG, BEIJING (CN); Penghai YIN, BEIJING (CN); Zuyu CHEN, BEIJING (CN); Suizi JIA, BEIJING (CN); Jianbin XU, BEIJING (CN); Jing HU, BEIJING (CN); Xuedong ZHANG, BEIJING (CN); Nengxiong XU, BEIJING (CN); Jintong WANG, BEIJING (CN); Ziqi YAN, BEIJING (CN); Yifan ZHANG, BEIJING (CN); Yusheng YANG, BEIJING (CN)

(73) Assignees: CHINA INSTITUTE OF WATER RESOURCES AND HYDROPOWER RESEARCH, BEIJING (CN); China University of Geosciences (Beijing), BEIJING (CN)

(21) Appl. No.: 19/561,480

(22) Filed: Mar. 9, 2026

Related U.S. Application Data
(63) Continuation of application No. PCT/CN2025/144647, filed on Dec. 23, 2025.

(30) Foreign Application Priority Data
Dec. 26, 2024 (CN) 202411940893.8

(51) Int. Cl. G06F 30/13

(52) U.S. Cl. CPC G06F 30/13

(57) ABSTRACT

The present invention discloses an evaluation method and system for impacts of groundwater level fluctuations on safety of subway stations based on centrifugal model tests, and a storage medium, and relates to the field of research on impacts of groundwater level fluctuations on underground space safety. The method includes: in a centrifugal test model, after a centrifuge reaches an acceleration value and stably operates for a period of time, recording stresses, strains, deformations and displacements of the structures of subway stations and labeling as first state data of a subway structure; gradually raising a water level, and recording second state data of the structures of the subway stations; comparing and analyzing the second state data with the first state data, and determining the impacts of groundwater level rise on safety and anti-floating stability of the structures of the subway stations, and impact factors; and lowering the water level, recording third state data of the structures of the subway stations, and comparing and analyzing the third state data with the first and second state data to analyze the impact of groundwater decrease on the safety of the structures of the subway stations. The present invention aims to assess and analyze the impacts of groundwater level fluctuations on the anti-floating stability and the structural safety of the subway stations.

### CROSS-REFERENCE TO RELATED APPLICATION

This application is a continuation of the international application PCT/CN2025/144647 filed on Dec. 23, 2025, which claims the priority benefit to China application CN202411940893.8 filed on Dec. 26, 2024, the contents of the above identified applications are herein incorporated by reference in their entirety and made a part of this specification.

### TECHNICAL FIELD

The present invention relates to the field of research on groundwater level fluctuations, and more particularly, relates to an analysis of the impacts of groundwater level fluctuations on the anti-floating stability of subway station structures based on centrifugal model tests, to analyze the floating deformation and failure modes of the structures under different water level conditions.

### BACKGROUND ART

Many cities around the world have experienced significant changes in the groundwater levels, such as Tokyo in Japan and some cities in China, which have experienced the phenomena of significant decreases and significant increases in groundwater levels.

In the late 1970s, the groundwater levels in a certain city of China were generally located within 10 meters below the surface, demonstrating abundant water resource endowments. With the rapid economic and social development, coupled with the fact that this city experienced the longest continuous dry years in its history in the early 21st century, the amount of groundwater extraction has significantly increased. As a result, the average burying depth of the groundwater in this city has decreased to approximately 25 meters. This long-term decrease in the groundwater level has led to a series of ecological and geological disasters such as betrunking of streams, disappearance of wetlands, groundwater pollution, and intensified ground subsidence, at a heavy cost. To solve these problems, this city began to implement a series of groundwater restoration measures, such as groundwater pressure extraction policies and introduction of water diversion projects. As these measures were gradually implemented, the groundwater level showed a significant recovery. At the same time, it is possible that the groundwater level may decrease due to some other reasons.

The raising and lowering of groundwater are likely to have adverse impacts on the engineering space of the existing underground structure, especially on subway projects with a burial depth within the raising and lowering variation area of the groundwater level, which may have risks such as floating and structural instability, as well as possible subsidence and cracking. However, at present, the phenomenon of the damage of groundwater level fluctuations to the subway projects is not clear, and conducting large-scale physical tests and prototype observations is severely constrained by sites, and also has extremely high time and economic costs.

For most geotechnical engineering structures, their stress states and deformation characteristics depend largely on the gravitational force they are subjected to. Especially for high earth-rock buildings, the gravitational force determines the stress and deformation characteristics. A geotechnical centrifuge can provide an artificial high-gravity field, to reproduce the traits of a prototype in a model geotechnical building.

The present invention uses a supergravity field formed by the centrifuge to achieve stress similarity between a small-scale model and a prototype structure, and has the advantage of using the small-scale model to simulate the prototype. The present invention has the advantages of accurately simulating the gravity field of the structure and a foundation, ensuring that model material withstands the same stress level as the prototype structure, researching large-scale prototype issues on the small-scale model, saving material space and having a relatively short test period.

### SUMMARY OF THE INVENTION

In view of this, the present invention provides an evaluation method and system for impacts of groundwater level fluctuations on safety of subway stations based on centrifugal model tests and a storage medium, aiming to assess and analyze the comprehensive impact of groundwater level fluctuations on the structures of the subway stations and simulate the dynamic changes of groundwater levels to explore the buoyancy and deformation impacts of the groundwater level rise on the subway stations. To achieve the above purpose, the present invention adopts the following technical solution:

An evaluation method for impacts of groundwater level fluctuations on safety of subway stations based on centrifugal model tests includes the following steps:
arranging subway station models in a foundation model, wherein the thickness of each stratum in the foundation model is determined by scaling down according to actual geological conditions in a scale ratio, and the sizes of the subway station models are also determined in the scale ratio accordingly; at the same time, considering the similarity in weight (the similarity relationship is provided below) in subway stations, steel or aluminum material is used to replace concrete and steel bar material in the subway stations; and using metal material to make the subway station models can make up for the disadvantage of concrete material being difficult to produce small-sized models;
burying the subway station models to a particular depth, wherein a lower part is a foundation soil body, and an upper part is an overlying soil body; one side of the subway station model is close to a transparent window of a model box; one side of the subway station model is tightly attached to the transparent window of the model box; and lubricating material such as silicone oil is applied therebetween to reduce the friction between the subway station model and the transparent window;
   acquiring the relevant data of the subway stations under different water levels, and on the basis of the basic principle of a centrifugal model, according to the relevant data of the subway stations, constructing a centrifugal test model of the foundation and the subway stations;
setting an initial water level in the centrifugal test model; starting a centrifuge; and after reaching a preset centrifuge acceleration value and stably operating for a period of time, recording stresses, strains, deformations and displacements of the structures of the subway stations and labeling as first state data of a subway structure;
   gradually raising the water level to a predetermined high test water level, and recording second state data of the structures of the subway stations;
comparing and analyzing the second state data with the first state data, and determining the impacts of the groundwater level rise on the safety and the anti-floating stability of the structures of the subway stations, and impact factors;
gradually lowering the water level to a predetermined low test water level, recording third state data of the structures of the subway stations, and comparing and analyzing the third state data with the first and second state data to analyze the impact of groundwater decrease on the safety of the structures of the subway stations; and
raising and lowering the test water level repeatedly, recording corresponding state data, and comparing and analyzing the multiple state data to analyze the impact of groundwater level fluctuations on the anti-floating stability and the structural safety of the subway stations.

Optionally, a coupling measurement method of a contact method, an image method and a laser method is used to measure the deformations and displacements of the subway station models and the soil bodies. The contact measurement method is achieved using a Linear Variable Differential Transformer (LVDT), the image measurement method is achieved using a Particle Image Velocimetry (PIV) method, and the laser displacement measurement method is achieved using a laser displacement sensor.

In the process of raising and lowering the water level and after reaching the preset water level, the following displacements are measured:
one end of the LVDT is fixed at the top of the subway station model, the LVDT passes through the overlying soil body of the station model, and the other end is fixed to a crossbeam fixed at the top of the model box; and the floating and sinking of the station model caused by water level changes inside the model are analyzed through a displacement change value of the LVDT.

The vertical displacement of the soil body on an upper surface of the model is monitored from the top of the model box using the laser displacement sensor, the displacement of the soil body and the subway station model is monitored from the front of the transparent window of the model box using a particle image velocimetry device, and the deformation of the station model and the foundation soil is analyzed;
the deformation of the soil body on the upper surface of the model is measured using the laser displacement sensor, which indirectly reflects the displacement and the deformation of the subway station model.

Optionally, pore water pressure gauges are placed in the soil body in each direction of the groundwater and subway centrifugal test model to monitor pore water pressure and obtain a water level value in the model through the pore water pressure, thereby calculating the buoyancy acting on the model station; soil pressure gauges are placed in the middle section of the station of the groundwater and subway centrifugal test model to monitor the pressure exerted on the station in all directions; and strain gauges are placed on four walls of the station of the groundwater and subway centrifugal test model to monitor the stress changes of the station in a centrifugal test.

Optionally, control signals of the centrifuge and signal acquisition are transmitted digitally through optical fibers.

Optionally, when the ratio of the prototype size of the subway to the size of the groundwater and subway centrifugal test model is n, a centrifuge acceleration aₘ is:

$${a}_{m} = \frac{{L}_{p}}{{L}_{m}} g = n g ;$$

where: Lₚ represents the prototype size; Lₘ represents the model size; and g represents a gravitational acceleration.

An evaluation system for impacts of groundwater level fluctuations on safety of subway stations based on centrifugal model tests includes:
a groundwater and subway centrifugal test model construction module: used for acquiring relevant data of subway stations under different water levels, and on the basis of the basic principle of a centrifugal model, according to the relevant data of the subway stations, constructing a centrifugal test model of a foundation and the subway stations;
a first state data acquiring module: used for setting an initial water level in the centrifugal test model; starting a centrifuge; and after reaching a preset centrifuge acceleration value and stably operating for a period of time, recording stresses, strains, deformations and displacements of the structures of the subway stations and labeling as first state data of a subway structure;
a second state data acquiring module: used for gradually raising the water level to a predetermined high test water level, and recording second state data of the structures of the subway stations;
a groundwater level rise evaluation module: used for comparing and analyzing the second state data with the first state data, and determining the impacts of the groundwater level rise on the safety and the anti-floating stability of the structures of the subway stations, and impact factors;
a third state data acquiring module: used for gradually lowering the water level to a predetermined low test water level, recording third state data of the structures of the subway stations, and comparing and analyzing the third state data with the first and second state data to analyze the impact of groundwater decrease on the safety of the structures of the subway stations; and
a stability and safety evaluation module: used for raising and lowering the test water level repeatedly, recording corresponding state data, and comparing and analyzing the multiple state data to analyze the impact of groundwater level fluctuations on the anti-floating stability and the structural safety of the subway stations.

Optionally, the raising and lowering of the groundwater level in the groundwater and subway centrifugal test model are controlled by supplying and discharging water into a water tank and through air pressure.

Optionally, the groundwater and subway centrifugal test model uses a laboratory water-pump water injection system to pump water into the centrifuge from underground; a connecting steel pipe and an explosion-proof water pipe on the centrifuge are connected to the bottom of the model box; a flow rate is set; and the water level in the model box is controlled to rise by a control valve.

Optionally, the laboratory water-pump water injection system is used to pump the water into the centrifuge from the underground; an explosion-proof hose is connected to the explosion-proof water pipe on the centrifuge; the explosion-proof hose is connected to the bottom of the model box through a side wall of the model box, and connected to a three-way adapter in a position 40 mm away from the bottom; both sides of the three-way adapter are connected to plastic hoses and then connected in parallel to the three-way adapter to form multiple rows of channels; a plastic hose is connected at each vertical outlet of the three-way adapter and arranged along the vertical direction of the model box; the length of the water pipe is 650 mm; a water outlet of the plastic water pipe is stopped with a water stop valve; the vertically arranged water pipes are drilled at intervals of 50 mm, with a total of 13 holes having a hole diameter of 3 mm; the hole diameters are kept consistent so that the water flows out evenly from the small holes; the flow rate is set, and the water level in the model box is controlled to rise evenly by the control valve; the arrangement positions of the hoses and the number and diameters of the holes are adjusted according to the simulated groundwater level position and fluctuation speed; the arrangement positions of the hoses are raised or lowered; and meanwhile, the number of the holes is increased or decreased and the hole diameters are adjusted.

A computer storage medium has a computer program stored therein, wherein when executed by a processor, the computer program implements the steps of any of the evaluation method for impacts of groundwater level fluctuations on safety of subway stations based on centrifugal model tests described above.

From the above technical solution, it can be seen that compared with the prior art, the present invention provides an evaluation method and system for impacts of groundwater level fluctuations on safety of subway stations based on centrifugal model tests and a storage medium, and has the following beneficial effects:
1. By constructing the groundwater and subway centrifugal test model, the impact of groundwater level fluctuations on subway stations and tunnel structures thereof can be accurately simulated. This method can take into account the actual change conditions of the groundwater levels and the stress characteristics of the subway structure under complex geological conditions, thereby providing more accurate prediction results.
2. The water level is gradually raised to different predetermined test heights and the stress data of the subway and the tunnel structure are recorded, which can dynamically analyze the impact of groundwater level fluctuations on the safety of the subway stations. This method can capture the subtle changes in the structural stresses of the subway stations during the water level changes, which is conducive to finding potential safety hazards in time.
3. The centrifuge is started to simulate the actual gravitational conditions, which can further verify the stability and the safety of the structures of the subway stations under the action of gravity. This is conducive to more accurately assessing the stress conditions and the safety performance of the structures of the subway stations during actual operation.

### BRIEF DESCRIPTION OF THE DRAWINGS

To more clearly describe the technical solutions in the embodiments of the present invention or in the prior art, the drawings required to be used in the description of the embodiments or the prior art will be simply presented below. Obviously, the drawings in the following description are merely embodiments of the present invention, and for those ordinary skilled in the art, other drawings can also be obtained according to the provided drawings without contributing creative labor.

FIG. 1 is a flow chart of the present invention;

FIG. 2 is a structural schematic diagram of the present invention;

FIG. 3a is a schematic diagram of a tunnel centrifugal model test of the present invention;

FIG. 3b is a schematic diagram of a tunnel centrifugal model test of the present invention;

FIG. 4 is a schematic diagram of a subway station test of the present invention;

FIG. 5a is a schematic diagram of a groundwater water level simulating hydraulic chamber of the present invention;

FIG. 5b is a schematic diagram of a pipeline of a groundwater water level simulating hydraulic chamber of the present invention.

### DETAILED DESCRIPTION OF THE INVENTION

Technical solutions in the embodiments of the present invention are described clearly and fully below in combination with the drawings in the embodiments of the present invention. Apparently, the described embodiments are merely part of the embodiments of the present invention, not all of the embodiments. Based on the embodiments in the present invention, all other embodiments obtained by those ordinary skilled in the art without contributing creative labor will belong to the protection scope of the present invention.

### Embodiment 1

The embodiment of the present invention discloses an evaluation method for impacts of groundwater level fluctuations on safety of subway stations based on centrifugal model tests, including the following steps:
arranging subway station models in a foundation model, wherein the thickness of each stratum in the foundation model is determined by scaling down according to actual geological conditions in a scale ratio, and the sizes of the subway station models are also determined in the scale ratio accordingly; at the same time, considering the similarity in weight (the similarity relationship is provided below) in subway stations, steel or aluminum material is used to replace concrete and steel bar material in the subway stations; and using metal material to make the subway station models can make up for the disadvantage of concrete material being difficult to produce small-sized models;
   burying the subway station models to a particular depth, wherein a lower part is a foundation soil body, and an upper part is an overlying soil body; one side of the subway station model is close to a transparent window of a model box; one side of the subway station model is tightly attached to the transparent window of the model box; and lubricating material such as silicone oil is applied therebetween to reduce the friction between the subway station model and the transparent window;
   step 1: acquiring the relevant data of the subway stations under different water levels, and on the basis of the basic principle of a centrifugal model, according to the relevant data of the subway stations, constructing a centrifugal test model of the foundation and the subway stations;
   step 2: setting an initial water level in the centrifugal test model; starting a centrifuge; and after reaching a preset centrifuge acceleration value and stably operating for a period of time, recording stresses, strains, deformations and displacements of the structures of the subway stations and labeling as first state data of a subway structure;
   step 3: gradually raising the water level to a predetermined high test water level, and recording second state data of the structures of the subway stations;
   step 4: comparing and analyzing the second state data with the first state data, and determining the impacts of the groundwater level rise on the safety and the anti-floating stability of the structures of the subway stations, and impact factors;
   step 5: gradually lowering the water level to a predetermined low test water level, recording third state data of the structures of the subway stations, and comparing and analyzing the third state data with the first and second state data to analyze the impact of groundwater decrease on the safety of the structures of the subway stations; and
   step 6: raising and lowering the test water level repeatedly, recording corresponding state data, and comparing and analyzing the multiple state data to analyze the impact of groundwater level fluctuations on the anti-floating stability and the structural safety of the subway stations.

Further, in step 3, in the process of raising the water level, the vertical displacement of the soil body and the station structure is monitored from the top using the laser displacement sensor, and the displacement of the soil body is monitored from the front of the transparent window of the model box using a particle image velocimetry device to determine the displacement situation of the soil body.

A coupling measurement method of a contact method, an image method and a laser method is used to measure the deformations and displacements of the subway station models and the soil bodies. The contact measurement method is achieved using a Linear Variable Differential Transformer (LVDT), the image measurement method is achieved using a Particle Image Velocimetry (PIV) method, and the laser displacement measurement method is achieved using a laser displacement sensor.

In the process of raising and lowering the water level and after reaching the preset water level, the following displacements are measured:
one end of the LVDT is fixed at the top of the subway station model, the LVDT passes through the overlying soil body of the station model, and the other end is fixed to a crossbeam fixed at the top of the model box; and the floating and sinking of the station model caused by water level changes inside the model are analyzed through a displacement change value of the LVDT.

The vertical displacement of the soil body on an upper surface of the model is monitored from the top of the model box using the laser displacement sensor, the displacement of the soil body and the subway station model is monitored from the front of the transparent window of the model box using a particle image velocimetry device, and the deformation of the station model and the foundation soil is analyzed; the deformation of the soil body on the upper surface of the model is measured using the laser displacement sensor, which indirectly reflects the displacement and the deformation of the subway station model

Further, in steps 3 to 4, pore water pressure gauges are placed in the soil body in each direction of the groundwater and subway centrifugal test model to monitor pore water pressure and obtain a water level value in the model through the pore water pressure, thereby calculating the buoyancy acting on the model station; soil pressure gauges are placed in the middle section of the station of the groundwater and subway centrifugal test model to monitor the pressure exerted on the station in all directions; and strain gauges are placed on four walls of the station of the groundwater and subway centrifugal test model to monitor the stress changes of the station in a centrifugal test.

In step 4, control signals of the centrifuge and signal acquisition are transmitted digitally through optical fibers.

Still further, when the ratio of the prototype size of the subway to the size of the groundwater and subway centrifugal test model is n, a centrifuge acceleration aₘ is:

$${a}_{m} = \frac{{L}_{p}}{{L}_{m}} g = n g ;$$

where: Lₚ represents the prototype size; Lₘ represents the model size; and g represents a gravitational acceleration.

A prototype size 1/n test model is placed in an ng centrifugal gravity field. If the self-weight of the test model is increased by n times, then the stress on each point in the model is the same as the stress on the corresponding point in the prototype. This is the similarity law of centrifugal model tests. Table 1 lists the similarity laws of the main parameters of the centrifugal model tests.

TABLE 1
Similarity Laws of Centrifugal Model Tests

| Feature | Dimension | Model-prototype ratio |
|---|---|---|
| Length | L | 1:n |
| Area | L² | 1:n² |
| Volume | L³ | 1:n³ |
| Force | F | 1:n² |
| Stress | FL⁻² | 1:1 |
| Strain | — | 1:1 |
| Displacement | L | 1:n |
| Density | ML⁻³ | 1:1 |
| Compression coefficient | L²F⁻¹ | 1:1 |
| Internal friction angle | — | 1:1 |
| Cohesive force | ML⁻¹T⁻² | 1:1 |
| Inertial acceleration | LT⁻² | n:1 |
| Self-weight stress | ML⁻¹T⁻² | 1:1 |
| Bearing capacity | ML⁻¹T⁻² | 1:1 |
| Modulus of compression | ML⁻¹T⁻² | 1:1 |
| Pore pressure | ML⁻¹T⁻² | 1:1 |
| Settling | L | 1:n |
| Time | T | 1:n² |

In the embodiment, the centrifuge used is an LXJ-4-450 type 450 g-ton geotechnical centrifuge. The LXJ-4-450 type 450 g-ton geotechnical centrifuge has a maximum rotation radius of 5.03 m, a maximum acceleration of 300 g, an effective load of 1.5 tons and an effective load capacity of 450 g-ton, and is driven by a DC motor with a power of 700 kW. The sizes of a test hanging basket are 1.5 m×1.0 m×1.5 m. At the beginning of the completion, the device scale ranks first in Asia and fourth in the world. Today, the centrifuge remains one of the largest centrifuges domestically, and has the capability to simulate geotechnical engineering projects such as 150-meter-high earth-rock dams, 150-meter-high slopes, and 150-meter-level underground caverns. The LXJ-4-450 large-scale geotechnical centrifuge adopts symmetrical rotating arms, double hanging baskets, and double-swinging mode. The main machine has a reasonable structure, operates smoothly, has the speed regulation accuracy of 0.1%, and is provided with a safety monitoring system. All the control and signal acquisition of the centrifuge are digitally transmitted through optical fibers and is provided with an advanced data acquisition system and a high-precision sensor, including a high-precision low-speed acquisition instrument (24-bit high-precision AD), a high-density high-speed acquisition instrument (with the highest sampling rate of 250 MHz), an optical fiber signal acquisition instrument, a high-definition (4800 pixels×3400 pixels), a high-speed (4000 frames/second) image acquisition system, and a PIV analysis system, which can perform real-time acquisition and processing on information such as soil pressure, pore water pressure, temperature, acceleration and displacement, and can meet the signal acquisition requirements for various static and dynamic processes such as vibration, shock and explosion.

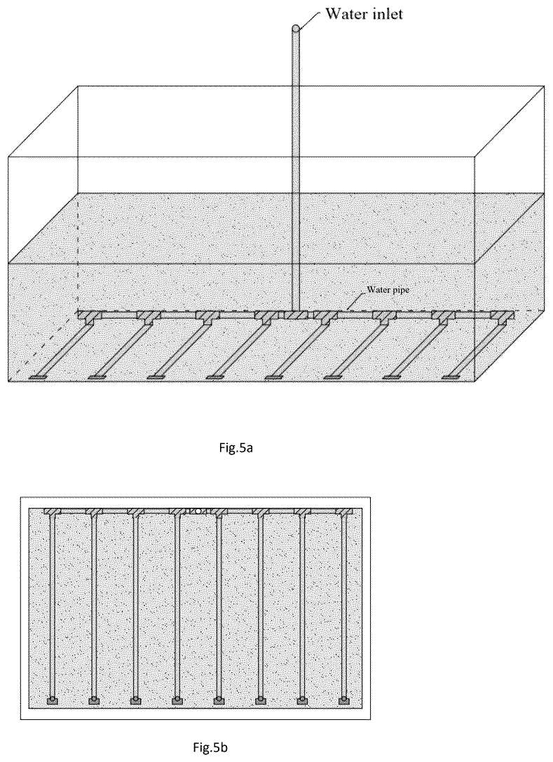

As shown in FIG. 5a and FIG. 5b, a laboratory is specially designed and manufactured to simulate the groundwater fluctuations in a soil sample. A water tank is installed at the bottom of the laboratory and below the soil sample. A perforated flow channel is arranged between the water tank and the soil sample for the inflow and outflow of water during the groundwater level fluctuations. A metal net and geotextiles are placed below the soil sample to prevent particle movement and maintain uniform water flow. The raising and lowering of the groundwater level are controlled by supplying and discharging water into the water tank and through air pressure.

Particle Image Velocimetry (PIV) is a non-contact optical flow measurement technique for measuring the distribution and changes of flow velocity in fluids (such as air and water). PIV technology tracks the movement of tiny suspended particles in the fluids to provide instantaneous velocity and turbulence characteristics of a flow field. A PIV analysis system is widely used in fields such as hydromechanics, environmental science, engineering tests and biomedical engineering. Specifically, the distance of a camera from the model box is 20 cm horizontally, and the height is raised by 15 cm from the plane level with the bottom of the model box. According to a light environment and the focusing distance of the camera, the camera should be commissioned on site. The camera can clearly and completely capture the model, including the soil body, a strip foundation and some of hydraulic rods. Color lines are used to serve as markers. The positional layering of the color lines is completed. The colors of the color lines are selected from bright red, but other colors can also be selected according to the sensitive color phase of a Particle Image Velocimetry (PIV) camera to ensure accurate identification. The coatings of the color lines should be selected from low-water-soluble coatings to prevent the coatings from flowing along with water and diffusing in the drainage process of the soil body.

In the process of the groundwater level fluctuations, the movement of particles inside the sample is monitored through displacement tracking image analysis technology.

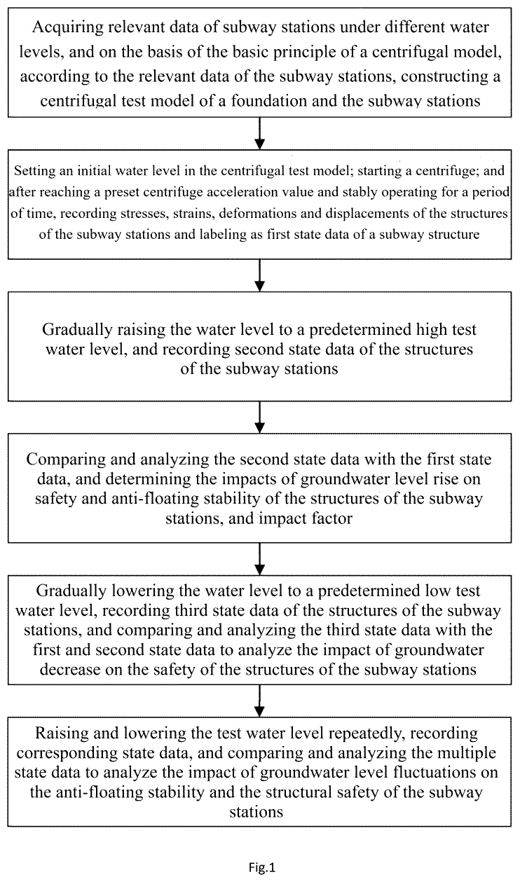

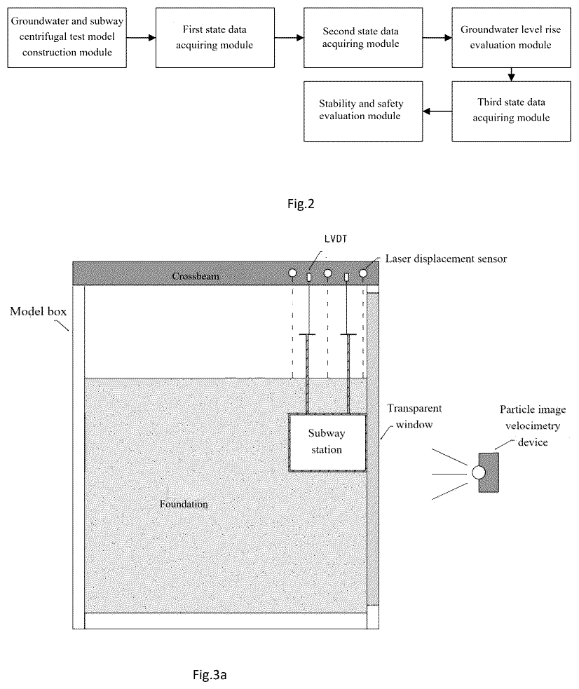

Corresponding to the method shown in FIG. 1, the present invention further discloses an evaluation system for impacts of groundwater level fluctuations on safety of subway stations based on centrifugal model tests, used for the implementation of the method shown in FIG. 1. The specific structure, as shown in FIG. 2, includes:
a groundwater and subway centrifugal test model construction module: used for acquiring the relevant data of the subway stations under different water levels, and on the basis of the basic principle of a centrifugal model, according to the relevant data of the subway stations, constructing a centrifugal test model of the foundation and the subway stations;
a first state data acquiring module: used for setting an initial water level in the centrifugal test model; starting a centrifuge; and after reaching a preset centrifuge acceleration value and stably operating for a period of time, recording stresses, strains, deformations and displacements of the structures of the subway stations and labeling as first state data of a subway structure;
a second state data acquiring module: used for gradually raising the water level to a predetermined high test water level, and recording second state data of the structures of the subway stations;
a groundwater level rise evaluation module: used for comparing and analyzing the second state data with the first state data, and determining the impacts of the groundwater level rise on the safety and the anti-floating stability of the structures of the subway stations, and impact factors;
a third state data acquiring module: used for gradually lowering the water level to a predetermined low test water level, recording third state data of the structures of the subway stations, and comparing and analyzing the third state data with the first and second state data to analyze the impact of groundwater decrease on the safety of the structures of the subway stations; and
a stability and safety evaluation module: used for raising and lowering the test water level repeatedly, recording corresponding state data, and comparing and analyzing the multiple state data to analyze the impact of groundwater level fluctuations on the anti-floating stability and the structural safety of the subway stations. Further, the raising and lowering of the groundwater level in the groundwater and subway centrifugal test model are controlled by supplying and discharging water into a water tank and through air pressure.

Further, the groundwater and subway centrifugal test model uses a laboratory water-pump water injection system to pump water into the centrifuge from underground; a connecting steel pipe and an explosion-proof water pipe on the centrifuge are connected to the bottom of the model box; a flow rate is set; and the water level in the model box is controlled to rise by a control valve.

Further, the laboratory water-pump water injection system is used to pump the water into the centrifuge from the underground; an explosion-proof hose is connected to the explosion-proof water pipe on the centrifuge; the explosion-proof hose is connected to the bottom of the model box through a side wall of the model box, and connected to a three-way adapter in a position 40 mm away from the bottom; both sides of the three-way adapter are connected to plastic hoses and then connected in parallel to the three-way adapter to form multiple rows of channels; a plastic hose is connected at each vertical outlet of the three-way adapter and arranged along the vertical direction of the model box; the length of the water pipe is 650 mm; a water outlet of the plastic water pipe is stopped with a water stop valve; the vertically arranged water pipes are drilled at intervals of 50 mm, with a total of 13 holes having a hole diameter of 3 mm; the hole diameters are kept consistent so that the water flows out evenly from the small holes; and the flow rate is set, and the water level in the model box is controlled to rise evenly by the control valve. The arrangement positions of the hoses and the number and diameters of the holes are adjusted according to the simulated groundwater level position and fluctuation speed; the arrangement positions of the hoses are raised or lowered; and meanwhile, the number of the holes is increased or decreased and the hole diameters are adjusted.

Further, the raising and lowering of the groundwater level in the groundwater and subway centrifugal test model are controlled by supplying and discharging water into a water tank and through air pressure.

Further, the groundwater and subway centrifugal test model uses a laboratory water-pump water injection system to pump water into the centrifuge from underground; a connecting steel pipe and an explosion-proof water pipe on the centrifuge are connected to the bottom of the model box; a flow rate is set; and the water level in the model box is controlled to rise by a control valve.

In the present embodiment, the laboratory water-pump water injection system is used to pump the water into the centrifuge from the underground; an explosion-proof hose is connected to the explosion-proof water pipe on the centrifuge; the explosion-proof hose is connected to the bottom of the model box through a side wall of the model box, and connected to a three-way adapter in a position 40 mm away from the bottom; both sides of the three-way adapter are connected to plastic hoses and then connected in parallel to the three-way adapter to form multiple rows of channels; a plastic hose is connected at each vertical outlet of the three-way adapter and arranged along the vertical direction of the model box; the length of the water pipe is 650 mm; a water outlet of the plastic water pipe is stopped with a water stop valve; the vertically arranged water pipes are drilled at intervals of 50 mm, with a total of 13 holes having a hole diameter of 3 mm; the hole diameters are kept consistent so that the water flows out evenly from the small holes; and the flow rate is set, and the water level in the model box is controlled to rise evenly by the control valve.

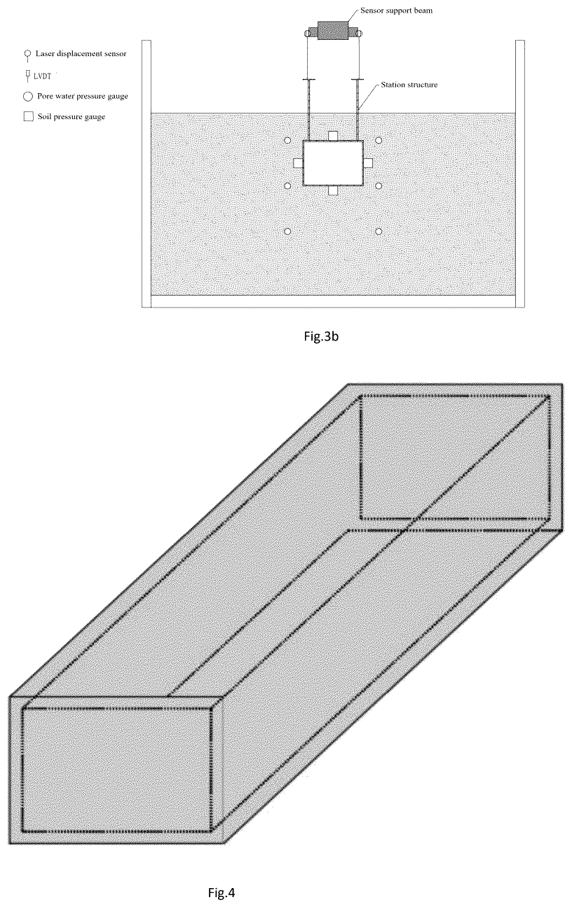

Under each water level condition, data from the sensors are collected comprehensively, and the stress state and the stability of the structure under different water level conditions are analyzed and assessed. Soil body displacements are monitored from the top using the laser displacement sensors (eight). A rigid rod is connected above the station structure. The rigid rod protrudes from the surface of the soil body, and on the upper end of the rod, a contact platform is made, and LVDT displacement meters (totally six, with a maximum stroke of 30 mm) are arranged to monitor the displacement of the station structure. The position distribution map of the probing rod is shown in FIG. 3a. The soil body displacement is monitored from the transparent front of the model box using a Particle Image Velocimetry (PIV) instrument. Pore water pressure gauges (totally seven, with a measurement range of 0-800 kPa) are placed in the soil body in each direction near the model station to monitor the pore water pressure and calculate the buoyancy acting on the model station through the pore water pressure.

In the present embodiment, geotextiles are wrapped around the periphery of the hose to prevent excessive water outflow pressure at the hole opening from causing shock on the foundation soil, resulting in soil body damage. At the same time, wrapping with the geotextiles also prevents the foundation soil body from blocking the pipe hole and entering a pipe body. The pipe diameter, and the size and the number of holes can be adjusted according to the water supply speed requirements. The periphery of the hose is filled with sand gravel. The sand gravel plays a support role for the hose, so as to reduce the deformation of the hose caused by the pressure generated by the overlying foundation model and reduce the impact of the pipe diameter change caused by the hose deformation on the water flow rate.

Finally, the present embodiment discloses a computer storage medium. The computer storage medium has a computer program stored therein, and when executed by a processor, the computer program implements the steps of any of the evaluation method for impacts of groundwater level fluctuations on safety of subway stations based on centrifugal model tests described above.

### Embodiment 2

The only difference between the present embodiment and embodiment 1 is as follows:

As shown in FIG. 3a, FIG. 3b and FIG. 4, the total mass of the test model=model box mass (607 kg)+soil body mass (1094.86 kg)+reaction frame and crossbeam weight (500.33 kg)+subway tunnel weight (7.57 kg)=2209.76 kg.

Assuming that: a centrifugal field is N times the gravitational acceleration g, i.e., N=prototype size/model size, then variable scale relationships are as follows:

$$\begin{matrix}\frac{{L}_{p}}{{L}_{m}} = N ; \\ \frac{{H}_{p}}{{H}_{m}} = N ; \\ \frac{{σ}_{p}}{{σ}_{m}} = 1 ;\end{matrix}$$

Lₚ and Lₘ represent a basic prototype width and a basic model width respectively, in meters;
Hₚ and Hₘ represent a prototype foundation depth and a model foundation depth respectively, in meters;
σₚ and σₘ represent a prototype foundation soil pressure and a model foundation soil pressure respectively, in kPa;

$${L}_{p} = 150 L {m}_{max} = 1.2 ;$$

According to the similarity principle and considering the prototype length and the inner length of the model box, Lₘ=1 is taken as the scale ratio (N), calculated as:

$$N = \frac{{L}_{p}}{{L}_{m}} = 150 ;$$

Other length dimensions of the station model are simultaneously reduced according to the calculated scale ratio.

Therefore, the centrifuge acceleration (a) is calculated as:

$$a = N \cdot g = 150 g ;$$

In the process of soil body preparation, first, an oily lubricant is evenly applied to four walls of the model box; and a sample is made by a sanding method, in several layers. More specific steps are as follows:
S1: soil sample arrangement and compaction: arranging and compacting a soil sample in a model container to ensure that the soil sample is firmly and accurately aligned; and arranging a necessary monitoring device in a structure and a soil layer.
S2: setting an initial water level and simulating normal groundwater level conditions: recording the buoyancy acting on the structure and the stability in an initial state.
S3: centrifugal loading and data recording: starting a centrifuge to simulate the actual gravitational conditions; gradually raising a water level to different predetermined test heights to simulate the process of groundwater level rise; and after each adjustment of the water level, recording the buoyancy changes and response situations of a station and a tunnel structure.
S4: using a laboratory water-pump water injection system to pump water to a centrifuge from the underground; connecting a connecting steel pipe and an explosion-proof water pipe on the centrifuge to the bottom of the model box; setting a flow rate; and controlling the water level in the model box to rise by a control valve.
S5: water level rise: setting an initial water level height, injecting water for several times, reaching heights successively, standing for 10 minutes.

Specific test steps include: first, hoisting and fixing the fabricated test model to the centrifuge, and then installing and testing each monitoring apparatus. At the beginning of the test, the initial water level is set at the bottom of the model box; the centrifugal acceleration is increased in 25 g increments stepwise and is loaded for 6 times. Once the acceleration at each stage is loaded to a set value and operation is maintained for 10 min, the loading process of a next stage is entered. After the centrifugal acceleration reaches 150 g, the initially set groundwater level is started to be raised. The rising speed of the groundwater level should meet the actual environment, i.e., to avoid the generation of excess pore water pressure.

Under each water level condition, data from the sensors are collected comprehensively, including buoyancy, pressure, stress and displacement, and the stress state and the stability of the structure under different water level conditions are analyzed and assessed. The vertical displacements of the soil body and the station structure are monitored from the top using two laser displacement sensors, and the soil body displacement is monitored from the transparent front of the model box using a Particle Image Velocimetry (PIV) instrument. 11 pore water pressure gauges are placed in the soil body in each direction near the model station to monitor the pore water pressure and calculate the buoyancy acting on the model station through the pore water pressure. 4 soil pressure gauges are placed in the middle section of the model station to monitor the pressure exerted on the model station in all directions. Strain gauges are placed on four walls of the model station to monitor the stress changes of the model station in the centrifugal test.

Each embodiment in the description is described in a progressive way. The difference of each embodiment from each other is the focus of explanation. The same and similar parts among all of the embodiments can be referred to each other. For the device disclosed by the embodiments, because the device corresponds to a method disclosed by the embodiments, the device is simply described. Refer to the description of the method part for the related part.

The above description of the disclosed embodiments enables those skilled in the art to realize or use the present invention. Many modifications made to these embodiments will be apparent to those skilled in the art. General principles defined herein can be realized in other embodiments without departing from the spirit or scope of the present invention. Therefore, the present invention will not be limited to these embodiments shown herein, but will conform to the widest scope consistent with the principles and novel features disclosed herein.

1. An evaluation method for impacts of groundwater level fluctuations on safety of subway stations based on centrifugal model tests, comprising the following steps:
acquiring relevant data of subway stations under different water levels, and on the basis of the basic principle of a centrifugal model, according to the relevant data of the subway stations, constructing a centrifugal test model of a foundation and the subway stations;
setting an initial water level in the centrifugal test model; starting a centrifuge; and after reaching a preset centrifuge acceleration value and stably operating for a period of time, recording stresses, strains, deformations and displacements of the structures of the subway stations and labeling as first state data of a subway structure;
gradually raising the water level to a predetermined high test water level, and recording second state data of the structures of the subway stations;
comparing and analyzing the second state data with the first state data, and determining the impacts of groundwater level rise on safety and anti-floating stability of the structures of the subway stations, and influence factors;
gradually lowering the water level to a predetermined low test water level, recording third state data of the structures of the subway stations, and comparing and analyzing the third state data with the first and second state data to analyze the impact of groundwater decrease on the safety of the structures of the subway stations;
raising and lowering the test water level repeatedly, recording corresponding state data, and comparing and analyzing the multiple state data to analyze the impact of groundwater level fluctuations on the anti-floating stability and the structural safety of the subway stations;
placing pore water pressure gauges in a soil body in each direction of the groundwater and subway centrifugal test model to monitor pore water pressure and obtain a water level value in the model through the pore water pressure, thereby calculating a buoyancy acting on the model station; placing soil pressure gauges in a middle section of the station of the groundwater and subway centrifugal test model to monitor the pressure exerted on the station in all directions; and placing strain gauges on four walls of the station of the groundwater and subway centrifugal test model to monitor the stress changes of the station in a centrifugal test, wherein when the ratio of the prototype size of a subway to the size of the groundwater and subway centrifugal test model is n, a centrifuge acceleration aₘ is:
$${a}_{m} = \frac{{L}_{p}}{{L}_{m}} g = n g ;$$
where: Lₚ represents the prototype size; Lₘ represents the model size; and g represents a gravitational acceleration;
in the process of raising and lowering the water level and after reaching the preset water level, measuring the following displacements:
fixing one end of a linear variable differential transformer at the top of the subway station model, the linear variable differential transformer passing through an overlying soil body of the station model, and fixing the other end to a crossbeam fixed at the top of a model box; and analyzing the floating and sinking of the station model caused by water level changes inside the model through a displacement change value of the linear variable differential transformer;
monitoring the vertical displacement of the soil body on an upper surface of the model from the top of the model box using a laser displacement sensor, monitoring the displacement of the soil body and the subway station model from the front of a transparent window of the model box using a particle image velocimetry device, and analyzing the deformation of the station model and foundation soil; and
measuring the deformation of the soil body on the upper surface of the model using the laser displacement sensor, which indirectly reflects the displacement and the deformation of the subway station model.

2. The evaluation method for impacts of groundwater level fluctuations on safety of subway stations based on centrifugal model tests according to claim 1, wherein control signals of the centrifuge and signal acquisition are transmitted digitally through optical fibers.

3. An evaluation system for impacts of groundwater level fluctuations on safety of subway stations based on centrifugal model tests, using the evaluation method for impacts of groundwater level fluctuations on safety of subway stations based on centrifugal model tests according claim 1, comprising:
a groundwater and subway centrifugal test model construction module: used for acquiring relevant data of subway stations under different water levels, and on the basis of the basic principle of a centrifugal model, according to the relevant data of the subway stations, constructing a centrifugal test model of a foundation and the subway stations;
a first state data acquiring module: used for setting an initial water level in the centrifugal test model; starting a centrifuge; and after reaching a preset centrifuge acceleration value and stably operating for a period of time, recording stresses, strains, deformations and displacements of the structures of the subway stations and labeling as first state data of a subway structure;
a second state data acquiring module: used for gradually raising the water level to a predetermined high test water level, and recording second state data of the structures of the subway stations;
a groundwater level rise evaluation module: used for comparing and analyzing the second state data with the first state data, and determining the impacts of the groundwater level rise on the safety and the anti-floating stability of the structures of the subway stations, and impact factors;
a third state data acquiring module: used for gradually lowering the water level to a predetermined low test water level, recording third state data of the structures of the subway stations, and comparing and analyzing the third state data with the first and second state data to analyze the impact of groundwater decrease on the safety of the structures of the subway stations; and
a stability and safety evaluation module: used for raising and lowering the test water level repeatedly, recording corresponding state data, and comparing and analyzing the multiple state data to analyze the impact of groundwater level fluctuations on the anti-floating stability and the structural safety of the subway stations.

4. The evaluation system for impacts of groundwater level fluctuations on safety of subway stations based on centrifugal model tests according to claim 3, wherein the raising and lowering of the groundwater level in the groundwater and subway centrifugal test model are controlled by supplying and discharging water into a water tank and through air pressure.

5. The evaluation system for impacts of groundwater level fluctuations on safety of subway stations based on centrifugal model tests according to claim 3, wherein the groundwater and subway centrifugal test model uses a laboratory water-pump water injection system to pump water into the centrifuge from underground; a connecting steel pipe and an explosion-proof water pipe on the centrifuge are connected to the bottom of the model box; a flow rate is set; and the water level in the model box is controlled to rise by a control valve.

6. The evaluation system for impacts of groundwater level fluctuations on safety of subway stations based on centrifugal model tests according to claim 3, wherein the laboratory water-pump water injection system is used to pump the water into the centrifuge from the underground; an explosion-proof hose is connected to the explosion-proof water pipe on the centrifuge; the explosion-proof hose is connected to the bottom of the model box through a side wall of the model box, and connected to a three-way adapter in a position 40 mm away from the bottom; both sides of the three-way adapter are connected to plastic hoses and then connected in parallel to the three-way adapter to form multiple rows of channels; a plastic hose is connected at each vertical outlet of the three-way adapter and arranged along the vertical direction of the model box; the length of the water pipe is 650 mm; a water outlet of the plastic water pipe is stopped with a water stop valve; the vertically arranged water pipes are drilled at intervals of 50 mm, with a total of 13 holes having a hole diameter of 3 mm; the hole diameters are kept consistent so that the water flows out evenly from the small holes; the flow rate is set, and the water level in the model box is controlled to rise evenly by the control valve; the arrangement positions of the hoses and the number and diameters of the holes are adjusted according to the simulated groundwater level position and fluctuation speed; the arrangement positions of the hoses are raised or lowered; and meanwhile, the number of the holes is increased or decreased and the hole diameters are adjusted.

7. A computer storage medium, having a computer program stored therein, wherein when executed by a processor, the computer program implements the steps of the evaluation method for impacts of groundwater level fluctuations on safety of subway stations based on centrifugal model tests according to claim 1.
